(19) United States
(12) Patent Application Publication
(10) Pub. No.: US 2025/0070082 A1
(43) Pub. Date: Feb. 27, 2025

(54) SEMICONDUCTOR PACKAGE

(71) Applicant: Samsung Electronics Co., Ltd., Suwon-si (KR)

(72) Inventor: Sojeong HONG, Suwon-si (KR)

(73) Assignee: Samsung Electronics Co., Ltd., Suwon-si (KR)

(21) Appl. No.: 18/434,122

(22) Filed: Feb. 6, 2024

(30) Foreign Application Priority Data
Aug. 21, 2023 (KR) 10-2023-0108827

(51) Int. Cl. H01L 25/065; H01L 23/00; H01L 23/29; H01L 23/31

(52) U.S. Cl. CPC H01L 25/0652; H01L 23/295; H01L 23/3128; H01L 24/32; H01L 24/48; H01L 24/73; H01L 2224/32145; H01L 2224/32225; H01L 2224/48228; H01L 2224/73265; H01L 2924/181

(57) ABSTRACT

A semiconductor package including a substrate; a first chip structure and a second chip structure on the substrate, the first chip structure adjacent to the second chip structure, the first chip structure including a first step portion on an upper portion of the first chip structure, and the second chip structure including a second step portion on an upper portion of the second chip structure; and a mold sealing the first and second chip structures. The mold includes first fillers distributed in a first region between the first step portion and the second step portion, and second fillers distributed in a second region below the first region. A first content of the first fillers is greater than a second content of the second fillers.

### CROSS-REFERENCE TO RELATED APPLICATION(S)

This application claims the benefit of priority under 35 USC 119(a) to Korean Patent Application No. 10-2023-0108827 filed on Aug. 21, 2023 in the Korean Intellectual Property Office, the entire disclosure of which is incorporated herein by reference for all purposes.

### BACKGROUND

The present disclosure relates to semiconductor packages.

With the development of the electronics industry, demand for higher functionality, higher speed, and smaller electronic components is increasing. According to this trend, packages are being manufactured by mounting a plurality of chip structures (e.g., a plurality of chip stacks and a dummy chip) on a single interposer or package substrate. Visual variation may occur on the surface of a mold covering the gaps between the plurality of chip structures.

### SUMMARY

Example embodiments of the inventive concepts provide a semiconductor package having improved exterior quality.

Example embodiments of the inventive concepts provide a semiconductor package that includes a substrate; a first chip structure and a second chip structure on the substrate, the first chip structure adjacent to the second chip structure, the first chip structure including a first step portion on an upper portion of the first chip structure, and the second chip structure including a second step portion on an upper portion of the second chip structure; and a mold sealing the first chip structure and the second chip structure. The mold includes first fillers distributed in a first region between the first step portion and the second step portion, and second fillers distributed in a second region below the first region. A first content of the first fillers in the mold is greater than a second content of the second fillers in the mold.

Example embodiments of the inventive concepts further provide a semiconductor package that includes a substrate; a plurality of chip structures including a first chip structure and a second chip structure on the substrate, the first chip structure adjacent to the second chip structure; and a mold covering upper and side surfaces of the plurality of respective chip structures. The first chip structure includes a first step portion defining a first recess in an upper portion of the first chip structure. The mold includes first fillers in a first region between the first step portion of the first chip structure and the second chip structure, and second fillers in a second region below the first region, the second region is between a side surface of the first chip structure and a side surface of the second chip structure. A second content of the second filler in the second region is less than a first content of the first filler in the first region.

Example embodiments of the inventive concepts still further provide a semiconductor package that includes a substrate; a first chip structure and a second chip structure on the substrate, the first chip structure adjacent to the second chip structure; and a mold sealing the first and second chip structures. The first chip structure includes a first chip body and a first spacer, the first chip body including a plurality of first semiconductor chips, the first spacer including a first base portion and a first step portion on the first base portion, and the first base portion is on the first chip body. The second chip structure includes a second chip body and a second spacer, the second chip body including at least one dummy chip or a plurality of second semiconductor chips, the second spacer including a second base portion and a second step portion on the second base portion, and the second base portion is on the second chip body. A width between the first step portion and the second step portion is greater than a width between the first chip body and the second chip body.

### BRIEF DESCRIPTION OF DRAWINGS

The above and other aspects, features, and advantages of the inventive concepts will be more clearly understood from the following detailed description, taken in conjunction with the accompanying drawings, in which:

FIG. 1A is a plan view of a semiconductor package according to an some example embodiments of the inventive concepts, FIG. 1B is a cross-sectional view taken along line I1-I1′in FIG. 1A, and FIG. 1C is a cross-sectional view taken along line I2-I2′ in FIG. 1A;

FIG. 2A is a cross-sectional view of a semiconductor package according to a comparative example, FIG. 2B is a plan view illustrating the visual variation of the semiconductor package according to a comparative example, and FIG. 2C is a plan view of a semiconductor package according to some example embodiments of the inventive concepts;

FIG. 3A is a plan view of a semiconductor package according to some example embodiments of the inventive concepts, and FIG. 3B is a cross-sectional view taken along line II-II′ of FIG. 3A;

FIG. 4A is a plan view of a semiconductor package according to some example embodiments of the inventive concepts, and FIG. 4B is a cross-sectional view taken along line III-III′ of FIG. 4A;

FIG. 5A is a plan view of a semiconductor package according to some example embodiments of the inventive concepts, and FIG. 5B is a cross-sectional view taken along line IV-IV′ of FIG. 5A;

FIG. 6A is a plan view of a semiconductor package according to some example embodiments of the inventive concepts, and FIG. 6B is a cross-sectional view taken along line V-V′ of FIG. 6A; and

FIG. 7A is a plan view of a semiconductor package according to some example embodiments of the inventive concepts, FIG. 7B is a cross-sectional view taken along line VI-VI′ of FIG. 7A, and FIG. 7C is a cross-sectional view of a chip body in an some example embodiments.

### DETAILED DESCRIPTION

Hereinafter, with reference to the accompanying drawings, some example embodiments of the inventive concepts will be described. Unless otherwise specified, in this specification, terms such as ‘upper,’ ‘upper surface,’ ‘lower,’ ‘lower surface,’ ‘side’ and the like are based on the drawings, and actually, may vary depending on the direction in which the components are disposed.

Ordinal numbers such as “first,” “second,” “third,” or the like may be used as labels for specific elements, step portions, directions, or the like to distinguish various elements, step portions, directions, or the like from each other. Terms that are not described using “first,” “second,” or the like in the specification may still be referred to as “first” or “second” in the claims. Terms referenced by a specific ordinal number (e.g., “first” in a particular claim) may be described elsewhere with a different ordinal number (e.g., “second” in the specification or another claim).

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., +10%) around the stated numerical values or shapes. When ranges are specified, the range includes all values therebetween such as increments of 0.1%.

Also, for example, “at least one of A, B, and C” and similar language (e.g., “at least one selected from the group consisting of A, B, and C”) may be construed as A only, B only, C only, or any combination of two or more of A, B, and C, such as, for instance, ABC, AB, BC, and AC.

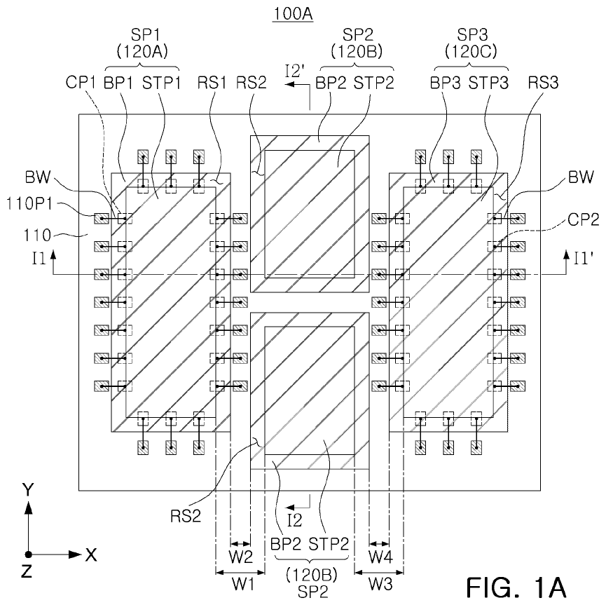

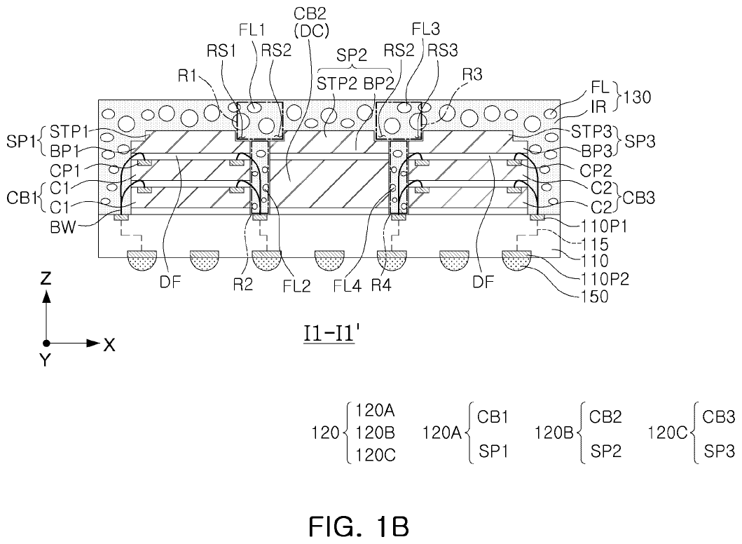

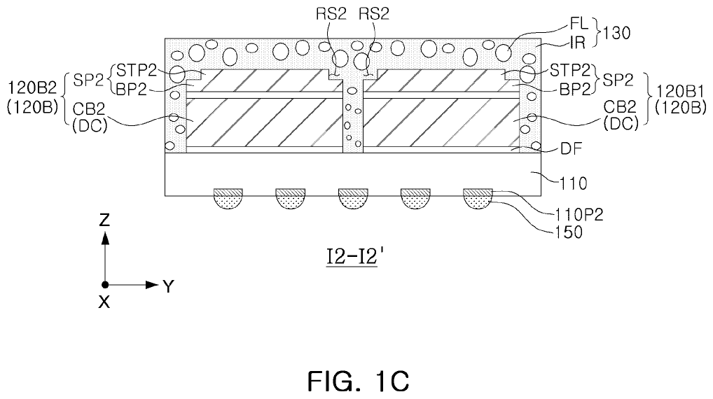

FIG. 1A is a plan view of a semiconductor package 100A according to some example embodiments of the inventive concepts, FIG. 1B is a cross-sectional view taken along line I1-I1′ in FIG. 1A, and FIG. 1C is a cross-sectional view taken along line I2-I2′ in FIG. 1A.

Referring to FIGS. 1A, 1B, and 1C, the semiconductor package 100A according to some example embodiments may include a substrate 110, a plurality of chip structures 120, and a mold 130. According to some example embodiments, semiconductor package 100A may further include a plurality of connection bumps 150.

The substrate 110 may be a substrate for a semiconductor package including a printed circuit board (PCB), a ceramic substrate, a glass substrate, or a tape wiring substrate. For example, the substrate 110 may be a double-sided printed circuit board (double-sided PCB) or a multilayer printed circuit board (PCB).

The substrate 110 may include upper pads 110P1, lower pads 110P2, and a wiring circuit 115 electrically connecting them. The upper pads 110P1 may be disposed on the upper surface of the substrate 110, and the lower pads 110P2 may be disposed on the lower surface of the substrate 110. The upper pads 110P1 and lower pads 110P2 may include at least one metal or an alloy composed of two or more metals among copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn) and carbon (C). The wiring circuit 115 may be electrically connected to at least some of the plurality of chip structures 120.

A plurality of connection bumps 150 may be disposed on the lower pads 110P2. The plurality of connection bumps 150 may be electrically connected to at least some of the plurality of chip structures 120 through the wiring circuit 115. The plurality of connection bumps 150 may include, for example, tin (Sn) or an alloy containing tin (Sn) (e.g., Sn-Ag-Cu). The plurality of connection bumps 150 may be electrically connected to external devices such as a module board and a system board.

A plurality of chip structures 120 may be disposed adjacently to each other on the substrate 110. For example, the plurality of chip structures 120 may include a first chip structure 120A, a second chip structure 120B, and a third chip structure 120C disposed adjacently to each other in the first direction (X-direction). In some example embodiments, the plurality of chip structures 120 may include two or five or more chip structures.

Each of the plurality of chip structures 120 may respectively include chip bodies CB1, CB2, and CB3 and spacers SP1, SP2, and SP3. The spacers SP1, SP2, and SP3 may provide recesses RS1, RS2, and RS3 on top of each of the plurality of chip structures 120. For example, the first chip structure 120A, the second chip structure 120B, and the third chip structure 120C may include first to third chip bodies (CB1, CB2, CB3) and first to third spacers (SP1, SP2, SP3), respectively. The spacers SP1, SP2, and SP3 may be attached to the chip bodies CB1, CB2, and CB3 by the adhesive film layer DF. The adhesive film layer (DF) may be a nonconductive film, a UV-sensitive film, an instant adhesive, a thermosetting adhesive, a laser curing adhesive, an ultrasonic curing adhesive, a nonconductive paste (NCP), or the like.

The chip bodies CB1, CB2, and CB3 may include at least one dummy chip DC and/or at least one semiconductor chip C1, C2. At least one dummy chip DC and at least one semiconductor chip C1 and C2 may be attached to the substrate 110 or attached to each other by the adhesive film layer DF. For example, the first chip body CB1 includes a plurality of first semiconductor chips C1 stacked in the vertical direction (Z-direction), the second chip body (CB2) includes a dummy chip (DC), and the third chip body CB3 may include a plurality of second semiconductor chips C2 stacked in the vertical direction (Z-direction). The second chip body CB2 may be disposed between the first chip body CB1 and the third chip body CB3.

In some example embodiments, the chip bodies (e.g., CB1, CB3) including at least one semiconductor chip among the chip bodies (e.g., CB1, CB2, CB3) may be mounted on the substrate 110 using a wire bonding method. For example, the first chip body CB1 and the third chip body CB3 may be electrically connected to the wiring circuit 115 of the substrate 110 through a bonding wire BW. The bonding wire (BW) may electrically connect the first connection pads CP1 of the first semiconductor chips C1 and the second connection pads CP2 of the second semiconductor chips C2 to the wiring circuit 115 of the board 110.

The at least one semiconductor chip (C1, C2) may include nonvolatile memory semiconductor chips, such as a Flash Memory, a Phase-change Random Access Memory (PRAM), a Magnetoresistive Random Access Memory (MRAM), a Ferroelectric Random Access Memory (FeRAM), or a Resistive Random Access Memory (RRAM), and/or volatile memory semiconductor chips, such as a Dynamic Random Access Memory (DRAM) or a Static Random Access Memory (SRAM).

In some example embodiments, the at least one semiconductor chip (C1, C2) may include logic chips such as a central processing unit (CPU), a graphics processing unit (GPU), a field programmable gate array (FPGA), an application processor (AP), a digital signal processor, a cryptographic processor, a microprocessor, a microcontroller, an analog-to-digital converter, an application-specific IC (ASIC), and the like.

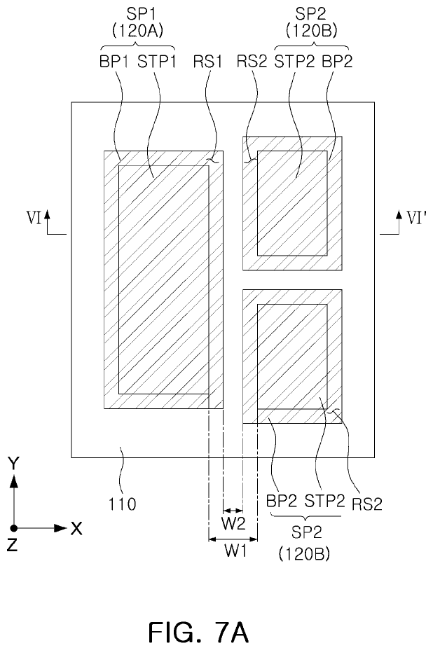

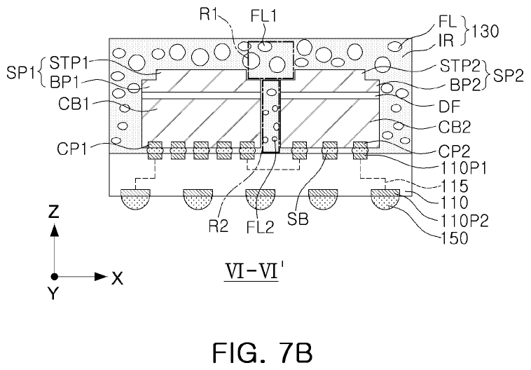

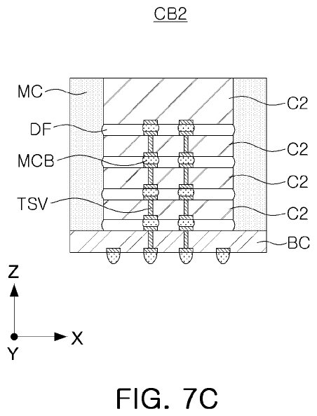

The first semiconductor chip C1 and the second semiconductor chip C2 may include the same type of semiconductor chip. For example, the first semiconductor chip C1 and the second semiconductor chip C2 may include a DRAM chip. In some example embodiments, the first semiconductor chip C1 and the second semiconductor chip C2 may include different types of semiconductor chips (see the example embodiments of FIGS. 7A and 7B).

The at least one dummy chip DC may include a material that may control warpage due to differences in thermal expansion coefficients between individual components constituting the semiconductor package 100A. For example, the at least one dummy chip DC may have a thermal expansion coefficient that is smaller than the thermal expansion coefficient of the first and second semiconductor chips C1 and C2 and the mold 130. The at least one dummy chip (DC) may be a silicon dummy, but is not limited thereto.

In some example embodiments, the at least one dummy chip may include two or more dummy chips DC. For example, as illustrated in FIG. 1A, two second chip structures 120B may be disposed between the first chip structure 120A and the third chip structure 120C. As illustrated in FIG. 1C, the two second chip structures 120B1 and 120B2 may each include a dummy chip DC. The second spacers SP2 may include second step portions STP2 providing second recesses RS2. For example, the second step portion STP2 of second chip structure 120B may define second recess RS2. The content of the fillers FL in the area between the opposing second step portions STP2 may be greater than the content of the fillers FL in the area between the dummy chips DC.

Two dummy chips DC may be disposed between the first semiconductor chips C1 and the second semiconductor chips C2, but the inventive concepts are not limited thereto. The positions, shapes, numbers, thermal expansion coefficients, or the like, of the first and second semiconductor chips (C1, C2) and the dummy chip (DC), may be determined by considering the integration degree, size, thermal expansion coefficient, or the like, of the semiconductor package according to some example embodiments.

The spacers SP1, SP2, and SP3 may be electrically insulated from the substrate 110. The spacers SP1, SP2, and SP3 may be silicon dies that are diced to have recesses RS1, RS2, and RS3 on the outside of the step portions STP1, STP2, and STP3. The spacers SP1, SP2, and SP3 may pressurize the top bonding wire BW to reduce the loop height of the top bonding wire BW. The thickness of the spacers SP1, SP2, and SP3 is not particularly limited, and the spacers SP1, SP2, and SP3 may have various thicknesses within a range that may secure the mold gap margin. The spacers SP1, SP2, and SP3 may include step portions STP1, STP2, and STP3 providing recesses RS1, RS2, and RS3 on top of the plurality of chip structures 120. For example, the step portions STP1, STP2 and STP3 of spacers SP1, SP2 and SP3 respectively define recesses RS1, RS2 and RS3 on top of chip structures 120A, 120B and 120C. The step portions STP1, STP2, and STP3 may have a width smaller than the width of the corresponding base portions BP1, BP2, and BP3 in the direction in which the plurality of chip structures 120 approach. For example, in the first direction (X-direction), the width of the first step portion (STP1) may be smaller than the width of the first base portion (BP1), and the width of the second step portion (STP2) may be smaller than the width of the second base portion (BP2).

The first spacer SP1 may include a first base portion BP1 on the first chip body CB1 and a first step portion STP1 on the first base portion BP1. The first chip structure 120A may have a first recess RS1 extending along at least a portion of the circumference of the first step portion STP1 in plan view.

The second spacer SP2 may include a second base portion BP2 on the second chip body CB2 and a second step portion STP2 on the second base portion BP2. The second chip structure 120B may have a second recess RS2 extending along at least a portion of the circumference of the second step portion STP2 in plan view.

The third spacer SP3 may include a third base portion BP3 on the third chip body CB3 and a third step portion STP3 on the third base portion BP3. The third chip structure 120C may have a third recess RS3 extending along at least a portion of the circumference of the third step portion STP3 in plan view.

The mold 130 may seal the plurality of chip structures 120. The mold 130 may cover the top and side surfaces of each of the plurality of chip structures 120. The mold 130 may include insulating resin (IR) and fillers (FL). The insulating resin (IR) may include, for example, a thermosetting resin such as an epoxy resin. The fillers FL may be inorganic fillers dispersed in the insulating resin IR. For example, the fillers FL may be silica particles with an average diameter of about 11 μm, but are not limited thereto. The mold 130 may be formed, for example, by hardening Epoxy Molding Compound (EMC).

According to some example embodiments, the step portions STP1, STP2, and STP3 of the spacers SP1, SP2, and SP3 improve the mobility of the fillers FL in the upper regions R1 and R3 between the plurality of chip structures 120, thereby limiting and/or preventing differences in content of fillers FL between the region above the plurality of chip structures 120 and the upper regions R1 and R3 between the plurality of chip structures 120, and thus limiting and/or preventing the visual variation caused thereby and improving the exterior quality of semiconductor packages.

The step portions STP1, STP2, and STP3 may improve the mobility of the fillers FL in the upper regions R1, R3 among the regions R1, R2, R3, and R4 between the plurality of chip structures 120. The first width W1 of the first region R1 between the first step portion STP1 and the second step portion STP2 may be larger than the second width W2 of the second region R2 between the first chip body CB1 and the second chip body CB2. The third width W3 of the third region R3 between the third step portion STP3 and the second step portion STP2 may be larger than the fourth width W4 of the fourth region R4 between the third chip body CB3 and the second chip body CB2. For example, the first width W1 and the third width W3 may be twice or more the corresponding second width W2 and fourth width W4. The second width W2 and the fourth width W4 may range from about 0.1 mm to about 0.8 mm, about 0.2 mm to about 0.7 mm, or about 0.3 mm to about 0.5 mm, but are not limited thereto. For convenience of explanation, the ratio between the sizes of the first to fourth regions R1, R2, R3, and R4 and the sizes of the fillers FL may not be clear in the figures, and the size of fillers FL illustrated in FIGS. 1B and 1C for example may be exaggerated and not to scale.

By the step portions STP1, STP2 and STP3, contents of the fillers FL may be different in the upper region (R1, R3) and the lower region (R2, R4) among the regions (R1, R2, R3, and R4) between the plurality of chip structures 120. For example, the mold 130 includes first fillers FL1 distributed in the first region R1, and second fillers FL2 distributed in the second region R2 below the first region R1, and in these regions, the first content of the first fillers FL1 may be greater than the second content of the second fillers FL2. The mold 130 includes third fillers FL3 distributed in the third region R3 and fourth fillers FL4 distributed in the fourth region R4 below the third region R3, and in these regions, the third content of the third fillers FL3 may be greater than the fourth content of the fourth fillers FL4. In some example embodiments, the first content and the third content may range from about 60 wt % to about 90 wt %, from about 60 wt % to about 80 wt %, or from about 60 wt % to about 70 wt %. The second content and the fourth content may range from about 30 wt % to about 60 wt %, about 40 wt % to about 60 wt %, or about 50 wt % to about 60 wt %. In some example embodiments, the first, second, third and fourth fillers FL1, FL2, FL3 and FL4 may be a same material.

The average diameter of the fillers FL1 and FL3 in the upper region R1 and R3 may be about 10 μm or more, for example, may range from about 10 μm to about 20 μm, from about m to about 15 μm, or from about 11 μm to about 13 μm. The average diameter of the fillers (FL2 and FL4) in the lower region (R2, R4) may be less than about 10 μm, for example, may range from about 5 μm to about 9 μm, from about 6 am to about 9 μm, or from about 7 μm to about 9 μm.

The content and size of the fillers FL are thus relatively increased in the upper regions R1 and R3 of the mold 130 between the plurality of chip structures 120, and color difference on the surface of the mold 130 may be limited and/or prevented, while the exterior quality of the semiconductor package 100A may be improved.

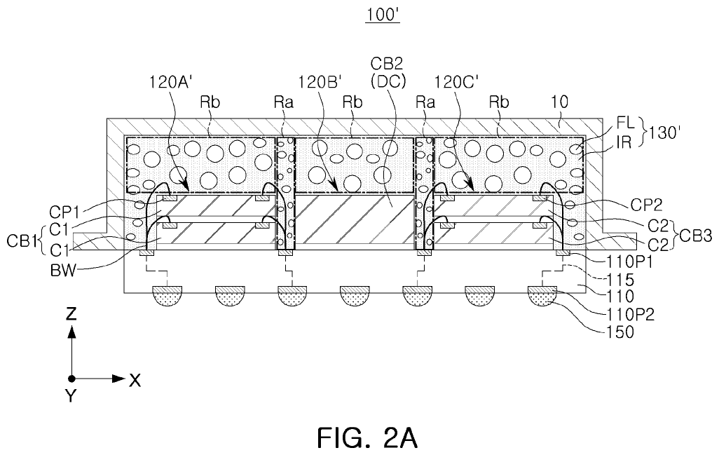

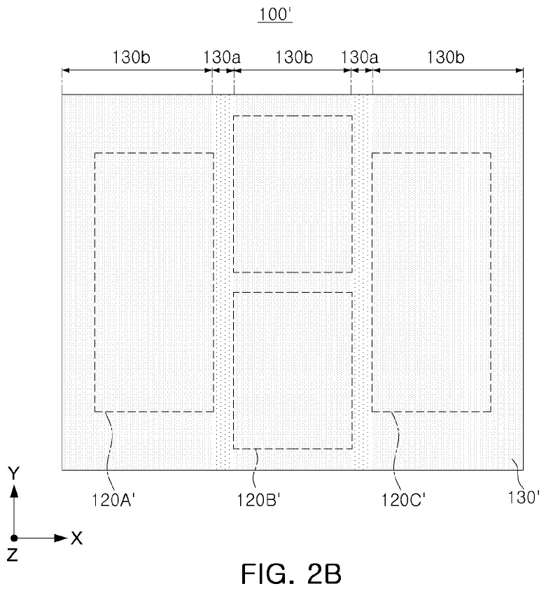

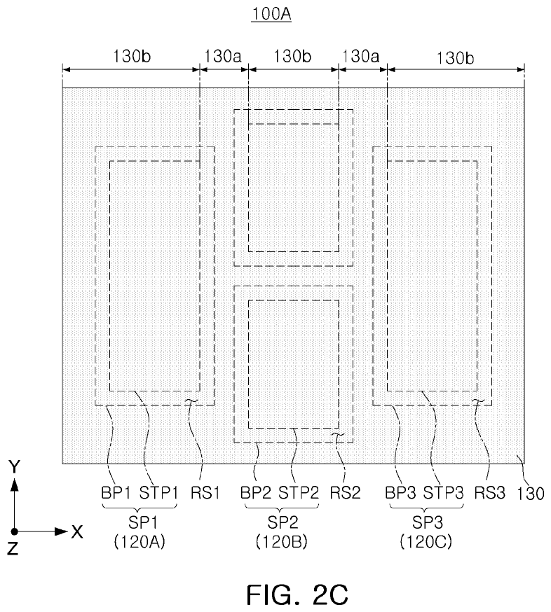

FIG. 2A is a cross-sectional view of a semiconductor package 100′ according to a comparative example, FIG. 2B is a plan view illustrating the visual variation of the semiconductor package 100′ according to an a comparative example, and FIG. 2C is a plan view of the semiconductor package 100A according to some example embodiments of the inventive concepts.

Referring to FIGS. 2A and 2B, the semiconductor package 100′ of the comparative example may have a color difference due to a difference in content of the fillers FL. In the process of forming the mold 130′ using the release film 10, the fluidity and mobility of the insulating resin (IR) and fillers (FL) may be reduced in the space between the plurality of chip structures 120A′, 120B′, and 120C′ adjacently to each other. Due to a decrease in the mobility of the fillers FL, local differences in the content of the fillers FL may occur. The content of fillers (FL) in the region (Ra) between the plurality of chip structures (120A′, 120B′, 120C′) may be smaller than the content of fillers FL in the region Rb above the plurality of chip structures 120A′, 120B′, and 120C′. The difference in content of these fillers (FL) in the upper region of the mold 130′ causes a difference in surface roughness of the mold 130′, and as a result, a color difference may occur between the first upper surface 130a and the second upper surface 130b of the mold 130′. In FIGS. 2A and 2B, the first upper surface 130a may be understood as the surface on the ‘Ra’ region, and the second upper surface 130b may be understood as the surface on the ‘Rb’ region.

Referring to FIG. 2C, the semiconductor package 100A of some example embodiments of the inventive concepts includes step portions STP1, STP2, and STP3 disposed on top of the chip structures 120A, 120B, and 120C, and the fillers FL may be evenly distributed in the upper area of the mold 130. As a result, color difference between the first upper surface 130a and the second upper surface 130b of the mold 130 may be limited and/or prevented and the exterior quality of the semiconductor package 100A may be improved. In FIG. 2C, the first upper surface 130a may be understood as the surface on the first region R1 and the third region R3 described with reference to FIGS. 1A to 1C.

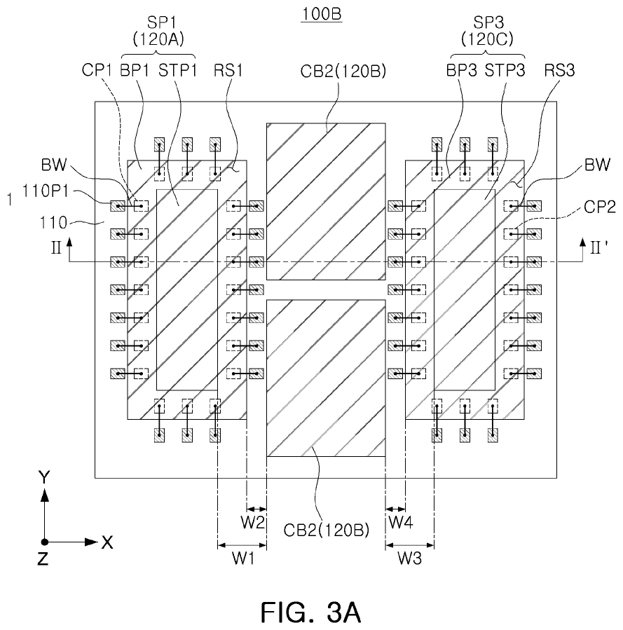

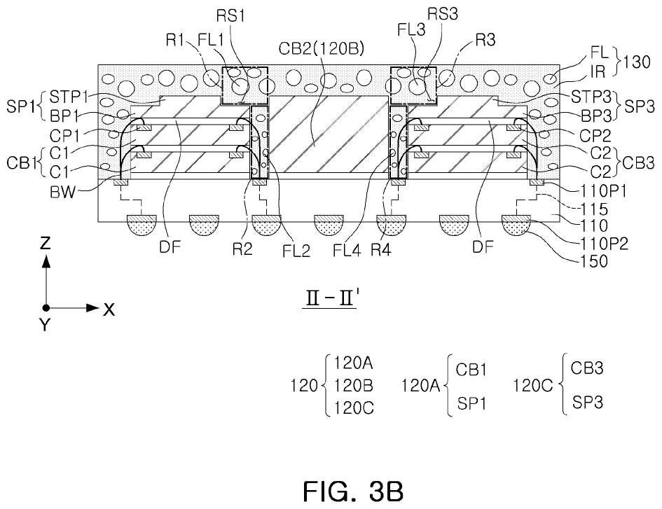

FIG. 3A is a plan view of a semiconductor package 100B according to some example embodiments of the inventive concepts, and FIG. 3B is a cross-sectional view taken along line II-II′ of FIG. 3A.

Referring to FIGS. 3A and 3B, the semiconductor package 100B of some example embodiments may have the same or similar features as those described with reference to FIGS. 1A to 2C, except that the step portions STP1 and STP3 are formed only in one of the chip structures (e.g., 120A, 120C) among the chip structures 120A, 120B, and 120C adjacently to each other.

The semiconductor package 100B may include a first chip structure 120A, a second chip structure 120B, and a third chip structure 120C adjacently to each other in the first direction (X-direction). The first chip structure 120A may include a first step portion STP1 providing a first recess RS1 in its upper portion. The third chip structure 120B may include a third step portion STP3 providing a third recess RS3 in its upper portion. The second chip structure 120B may not include a second recess and a second step portion. In some example embodiments, only the second chip structure 120B may include a recess and a step portion, and the first and second chip structures 120A and 120C may not include them.

The height of the second chip structure 120B from the upper surface of the substrate 110 may be substantially the same as the height of the first chip structure 120A. For example, the second chip structure 120B includes only the second chip body CB2, and the upper surface of the second chip body CB2 may be at the same level as the upper surface of the first chip structure 120A including the first chip body CB1 and the first spacer SP1. ‘Same level’ is a concept that includes tolerances that are not completely physically identical, and means that they are not intentionally designed differently.

The first width W1 of the first region R1 between the first step portion STP1 and the second chip structure 120B may be larger than the width W2 of the second region R2 between the first chip body CB1 and the second chip structure 120B. The third width W3 of the third region R3 between the third step portion STP3 and the second chip structure 120B may be larger than the fourth width W4 of the fourth region R4 between the third chip body CB3 and the second chip structure 120B.

The mold 130 includes first fillers FL1 distributed in the first region R1 and second fillers FL2 distributed in the second region R2 below the first region R1, and the first content of the first fillers FL1 may be greater than the second content of the second fillers FL2. The mold 130 includes third fillers FL3 distributed in the third region R3 and fourth fillers FL4 distributed in the fourth region R4 below the third region R3, and the third content of the third fillers FL3 may be greater than the fourth content of the fourth fillers FL4.

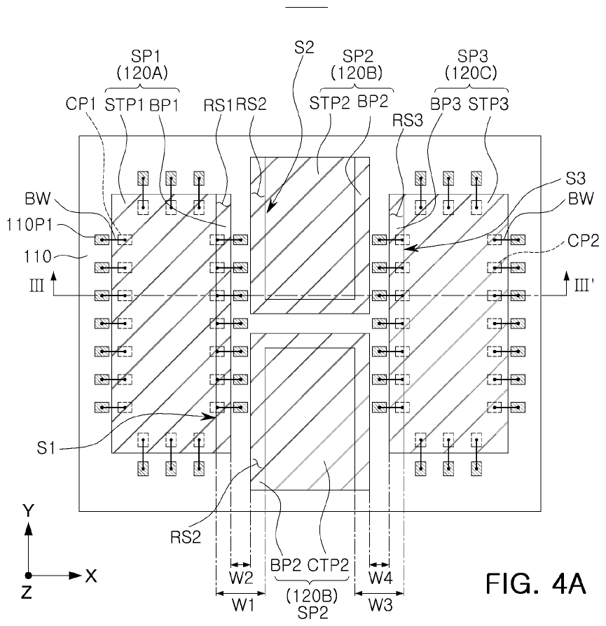

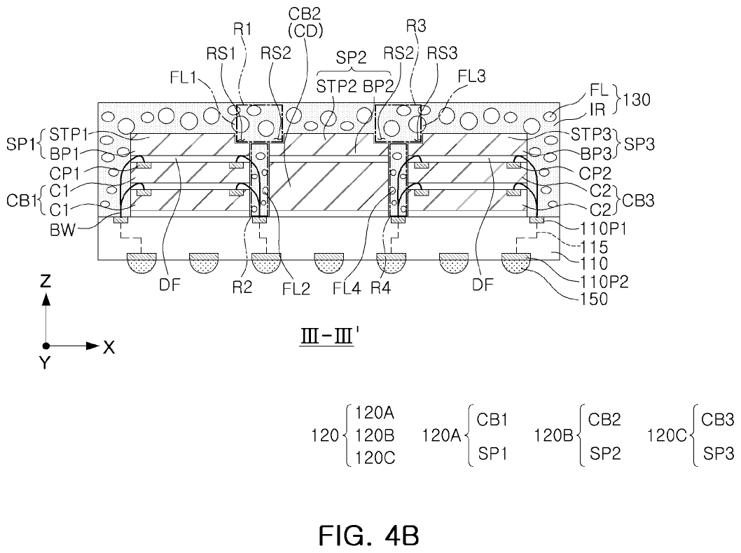

FIG. 4A is a plan view of a semiconductor package 100C according to some example embodiments of the inventive concepts, and FIG. 4B is a cross-sectional view taken along line III-III′ of FIG. 4A.

Referring to FIGS. 4A and 4B, the semiconductor package 100C of some example embodiments may have the same or similar features as those described with reference to FIGS. 1A to 3B, except that recesses (RS1, RS2, RS3) are formed only between chip structures (120A, 120B, and 120C) that are adjacent to each other.

The spacers SP1, SP2, and SP3 may provide recesses RS1, RS2, and RS3 on at least one side of the step portions STP1, STP2, and STP3 that face each other. The first step portion (STP1) and the second step portion (STP2) each have a first side (S1) and a second side (S2) opposing each other, the first recess (RS1) is provided on the first side (S1) of the first step portion (STP1), and the second recess RS2 may be provided on the second side S2 of the second step portion STP2. The third step portion (STP3) and the second step portion (STP2) have a third side (S3) and a second side (S2) respectively facing each other, the third recess (RS3) is provided on the third side (S3) of the third step portion (STP3), and the second recess (RS2) may be provided on the second side (S2) of the second step portion (STP2).

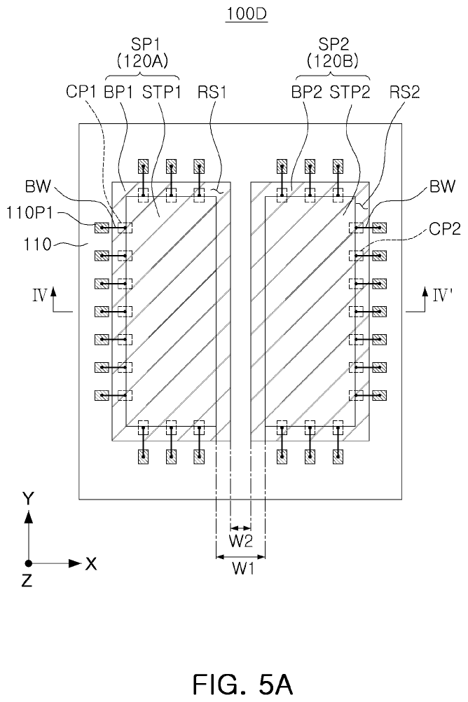

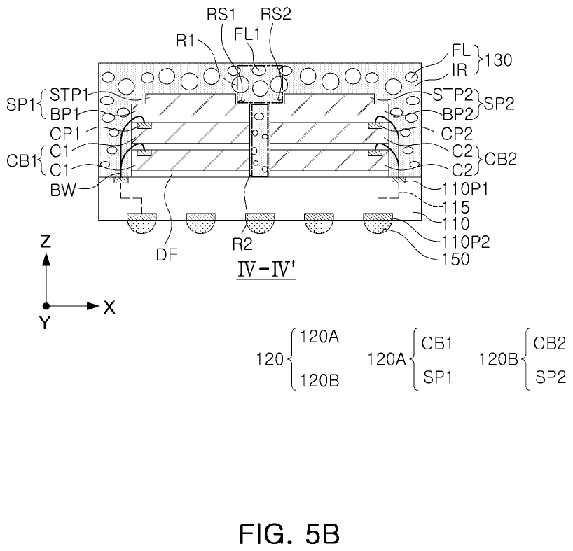

FIG. 5A is a plan view of a semiconductor package 100D according to some example embodiments of the inventive concepts, and FIG. 5B is a cross-sectional view taken along line IV-IV′ of FIG. 5A.

Referring to FIGS. 5A and 5B, the semiconductor package 100D of some example embodiments may have the same or similar features as those described with reference to FIGS. 1A to 4B, except that it does not include a dummy chip between the chip structures 120A and 120B.

The semiconductor package 100D may include a first chip structure 120A and a second chip structure 120B that are adjacently to each other. The first chip structure 120A may include at least one first semiconductor chip C1, and the second chip structure 120B may include at least one second semiconductor chip C2.

The first semiconductor chip C1 and the second semiconductor chip C2 may be attached to the substrate 110 by an adhesive film layer DF. The plurality of first semiconductor chips C1 and the plurality of second semiconductor chips C2 may be electrically connected to the wiring circuit 115 of the substrate 110 through a bonding wire BW.

The first semiconductor chip C1 and the second semiconductor chip C2 may include, for example, nonvolatile memory semiconductor chips such as flash memory, PRAM, MRAM, FeRAM, or RRAM, and/or volatile memory semiconductor chips such as DRAM or SRAM.

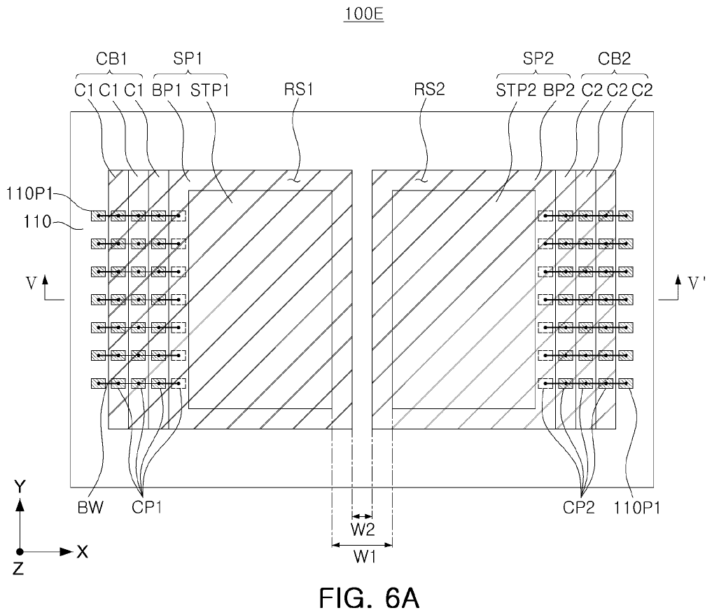

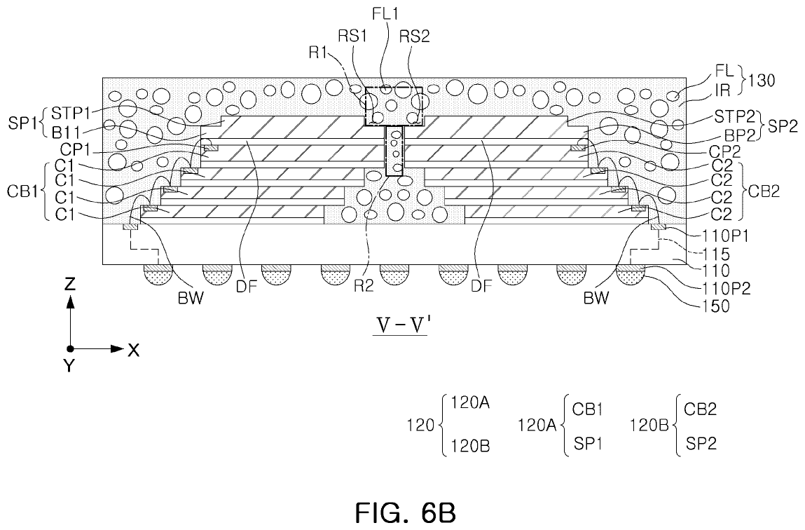

FIG. 6A is a plan view of a semiconductor package 100E according to some example embodiments of the inventive concepts, and FIG. 6B is a cross-sectional view taken along line V-V′ of FIG. 6A.

Referring to FIGS. 6A and 6B, the semiconductor package 100E of some example embodiments may have the same or similar features as those described with reference to FIGS. 1A to 5B, except that the chip structures 120A and 120B include semiconductor chips stacked to be offset in the horizontal direction (X-direction).

The first chip structure 120A may include a plurality of first semiconductor chips C1 stacked vertically (Z-direction). Each of the plurality of first semiconductor chips C1 may include first connection pads CP1 connected to the upper pads 110P1 of the substrate 110 through bonding wires BW. The plurality of first semiconductor chips C1 may be stacked to be offset in the horizontal direction (e.g., X-direction) so that each of the first connection pads CP1 is exposed in the vertical direction (Z-direction). A first spacer SP1 may be disposed on the uppermost first semiconductor chip C1 among the plurality of first semiconductor chips C1.

The second chip structure 120B may include a plurality of second semiconductor chips C2 stacked vertically (Z-direction). Each of the plurality of second semiconductor chips C2 may include second connection pads CP2 connected to the upper pads 110P1 of the substrate 110 through bonding wires BW. The plurality of second semiconductor chips C2 may be stacked to be offset in the horizontal direction (e.g., X-direction) so that each of the second connection pads CP2 is exposed in the vertical direction (Z-direction). A second spacer SP2 may be disposed on the uppermost second semiconductor chip C2 among the plurality of second semiconductor chips C2.

The first chip structure 120A and the second chip structure 120B may be disposed in an ‘A’ shape such that the uppermost first semiconductor chip (C1) and the uppermost second semiconductor chip (C2) are close to each other in the horizontal direction (X-direction). In some example embodiments, the semiconductor package 100E may further include a controller chip, a buffer chip, or the like disposed between the first chip structure 120A and the second chip structure 120B.

The distance between the first step portion STP1 and the second step portion STP2 may be greater than the distance between the first uppermost semiconductor chip C1 and the second uppermost semiconductor chip C2. The first content of the fillers FL in the first region R1 between the first step portion STP1 and the second step portion STP2 may be greater than the second content of fillers FL in the second region R2 between the uppermost first semiconductor chip C1 and the uppermost second semiconductor chip C2.

FIG. 7A is a plan view of the semiconductor package 100F according to some example embodiments of the inventive concepts, FIG. 7B is a cross-sectional view taken along line VI-VI′ of FIG. 7A, and FIG. 7C is a cross-sectional view of the second chip body CB2 of some example embodiments.

Referring to FIGS. 7A and 7B, the semiconductor package 100F of some example embodiments may have the same or similar features as those described with reference to FIGS. 1A to 6B, except that the chip structures 120 are flip-chip bonded to the substrate 110.

The semiconductor package 100F may include a first chip structure 120A and at least one second chip structure 120B. The first chip structure 120A and at least one second chip structure 120B may be electrically connected to the wiring circuit 115 of the substrate 110 through solder bumps SB. The first chip structure 120A may include a first chip body CB1 and a first spacer SP1. The second chip structure 120B may include a second chip body (CB2) and a second spacer (SP2).

The first chip body CB1 and the second chip body CB2 may include different types of semiconductor chips. The first chip body CB1 may include logic chips such as a central processing unit (CPU), a graphics processing unit (GPU), a field programmable gate array (FPGA), a digital signal processor, a cryptographic processor, a microprocessor, a microcontroller, an analog-to-digital converter, ASIC, and the like. The second chip body CB2 may include a memory chip such as DRAM, SRAM, PRAM, ReRAM, FeRAM, MRAM, and flash memory. In some example embodiments, the first chip body CB1 and the second chip body CB2 may include the same type of semiconductor chip. For example, both the first chip body CB1 and the second chip body CB2 may include a logic chip or a memory chip.

In some example embodiments, the second chip body CB2 may be provided as a high-performance memory device such as a high bandwidth memory (HBM) or a hybrid memory cube (HMC). For example, as illustrated in FIG. 7C, the second chip body CB2 may include a base chip BC, second semiconductor chips C2, and a molding compound layer MC.

The base chip BC may be a buffer chip including a plurality of logic elements and/or memory elements. Accordingly, the base chip BC may transmit signals from the second semiconductor chips C2 stacked on top to the outside, and may also transmit signals and power from the outside to the second semiconductor chips C2.

The second semiconductor chips C2 may be vertically stacked on the base chip BC. At least some of the second semiconductor chips C2 may include through-vias TSV. The second semiconductor chips C2 and the base chip BC may be electrically connected to each other through through-vias TSV and microbumps MCB. An adhesive film layer DF surrounding the microbumps MCB may be disposed under the second semiconductor chips C2. In some example embodiments, the microbumps MCB and the adhesive film layer DF may be omitted. The second semiconductor chips C2 may contain the same memory chip, for example, DRAM, SRAM, PRAM, ReRAM, FeRAM, MRAM, flash memory and the like.

The molding compound layer MC may seal at least a portion of each of the base chip BC and the second semiconductor chips C2. The molding compound layer MC may expose the top surface of the uppermost second semiconductor chip C2, but is not limited thereto. The molding compound layer MC may be formed of an insulating material such as EMC.

As set forth above, according to the inventive concepts, a semiconductor package having improved exterior quality may be provided by introducing a spacer having a step portion on an upper portion of chip structures.

While some example embodiments have been illustrated and described above, it will be apparent to those skilled in the art that modifications and variations could be made without departing from the scope of the inventive concepts as defined by the appended claims.

What is claimed is:

1. A semiconductor package comprising:
a substrate;
a first chip structure and a second chip structure on the substrate, the first chip structure adjacent to the second chip structure, the first chip structure including a first step portion on an upper portion of the first chip structure, and the second chip structure including a second step portion on an upper portion of the second chip structure; and
a mold sealing the first and second chip structures,
wherein the mold includes first fillers distributed in a first region between the first step portion and the second step portion, and second fillers distributed in a second region below the first region, and
a first content of the first fillers in the mold is greater than a second content of the second fillers in the mold.

2. The semiconductor package of claim 1, wherein a first width of the first region is greater than a second width of the second region.

3. The semiconductor package of claim 2, wherein the first width is at least twice the second width.

4. The semiconductor package of claim 2, wherein the second width ranges from about 0.2 mm to about 0.6 mm.

5. The semiconductor package of claim 1, wherein the first content ranges from about 60 wt % to about 70 wt %, and the second content ranges from about 50 wt % to about 60 wt %.

6. The semiconductor package of claim 1, wherein the first fillers and the second fillers include a same material.

7. The semiconductor package of claim 1, wherein an average diameter of the first fillers is about 10 μm or more, and an average diameter of the second fillers is less than about 10 μm.

8. The semiconductor package of claim 1, wherein the first step portion of the first chip structure defines a first recess extending along at least a portion of a circumference of the first chip structure in a plane, and
the second step portion of the second chip structure defines a second recess extending along at least a portion of a circumference of the second chip structure in a plane.

9. The semiconductor package of claim 8, wherein the first step portion and the second step portion respectively have a first side and a second side opposing each other,
the first recess is on the first side of the first step portion, and
the second recess is on the second side of the second step portion.

10. The semiconductor package of claim 1, wherein the first chip structure includes a first chip body, a first spacer on the first chip body, and a first adhesive film layer between the first chip body and the first space, the first spacer including the first step portion, and
the second chip structure includes a second chip body, a second spacer on the second chip body, and a second adhesive film layer between the second chip body and the second spacer, the second spacer including the second step portion.

11. The semiconductor package of claim 10, further comprising a bonding wire electrically connecting at least one of the first chip body and the second chip body to the substrate.

12. The semiconductor package of claim 10, wherein the first chip body includes one or more first semiconductor chips, and
the second chip body includes at least one dummy chip.

13. The semiconductor package of claim 12, further comprising a third chip structure adjacent to the second chip structure,
the third chip structure including a third chip body, a third spacer on the third chip body, and a third adhesive film layer between the third chip body and the third spacer, the third spacer including a third step portion,
wherein the mold includes third fillers distributed in a third region between the second step portion and the third step portion, and fourth fillers distributed in a fourth region below the third region, and
a third content of the third fillers is greater than a fourth content of the fourth fillers.

14. The semiconductor package of claim 10, wherein the first chip body includes one or more first semiconductor chips, and
the second chip body includes one or more second semiconductor chips.

15. The semiconductor package of claim 1, wherein the substrate includes an interconnection circuit electrically connected to at least one of the first chip structure and the second chip structure,
the semiconductor package further comprising a plurality of connection bumps below the substrate and electrically connected to the interconnection circuit.

16. A semiconductor package comprising:
a substrate;
a plurality of chip structures including a first chip structure and a second chip structure on the substrate, the first chip structure adjacent to the second chip structure; and
a mold covering upper and side surfaces of each of the plurality of chip structures,
wherein the first chip structure includes a first step portion defining a first recess in an upper portion of the first chip structure, and
the mold includes first fillers in a first region between the first step portion of the first chip structure and the second chip structure, and second fillers in a second region below the first region, the second region is between a side surface of the first chip structure and a side surface of the second chip structure, and a second content of the second filler in the second region is less than a first content of the first filler in the first region.

17. The semiconductor package of claim 16, wherein the first chip structure includes a plurality of first semiconductor chips stacked in a vertical direction, and a first spacer,
the first spacer including a base portion on the plurality of first semiconductor chips, and the first step portion is on the base portion,
wherein the plurality of first semiconductor chips are electrically connected to the substrate, and
the first spacer is electrically insulated from the substrate.

18. The semiconductor package of claim 16, wherein the second chip structure includes a second step portion defining a second recess in an upper portion of the second chip structure, and
the first region is between the first step portion and the second step portion.

19. A semiconductor package comprising:
a substrate;
a first chip structure and a second chip structure on the substrate, the first chip structure adjacent to the second chip structure; and
a mold sealing the first and second chip structures,
wherein the first chip structure includes a first chip body and a first spacer,
the first chip body including a plurality of first semiconductor chips, the first spacer including a first base portion and a first step portion on the first base portion, and the first base portion is on the first chip body, and
the second chip structure includes a second chip body and a second spacer,
the second chip body including at least one dummy chip or a plurality of second semiconductor chips, the second spacer including a second base portion and a second step portion on the second base portion, and the second base portion is on the second chip body,
wherein a distance between the first step portion and the second step portion is greater than a distance between the first chip body and the second chip body.

20. The semiconductor package of claim 19, wherein the first chip structure and the second chip structure are adjacent to each other along a first direction,
wherein in the first direction, a width of the first step portion is less than a width of the first base portion, and
a width of the second step portion is less than a width of the second base portion.
